(19) United States
(12) Patent Application Publication
(10) Pub. No.: US 2002/0019678 A1
(43) Pub. Date: Feb. 14, 2002

(54) Pseudo-emotion sound expression system

(76) Inventor: Takashi Mizokawa, Shizuoka (JP)

Correspondence Address: KNOBBE MARTENS OLSON & BEAR LLP, 620 NEWPORT CENTER DRIVE, SIXTEENTH FLOOR, NEWPORT BEACH, CA, 92660, US

(21) Appl. No.: 09/922,760

(22) Filed: Aug. 6, 2001

(30) Foreign Application Priority Data
Aug. 7, 2000 (JP) 2000-237853

(51) Int. Cl. G06F 17/00; H03G 3/00

(52) U.S. Cl. 700/94; 381/61

(57) ABSTRACT

A sound synthesis device is used for an interactive device which is capable of interacting with a user. The interactive device includes a pseudo-emotion generator which is programmed to generate plural pseudo emotions based on signals received by the interaction device. The sound synthesis device includes: (i) a sound data memory which stores a different sound assigned to each pseudo-emotion; (ii) a sound signal generator which receives signals from the pseudo-emotion generator and accordingly generates a sound signal for each pseudo emotion by retrieving the sound data stored in the sound data memory; (iii) a sound synthesizer which is programmed to synthesize a sound by combining each sound signal from the sound signal generator, wherein the user can recognize overall emotions generated in the interaction device; and (iv) an output device which outputs a synthesized sound to the user.

### BACKGROUND OF THE INVENTION

1. Field of the Invention

This invention relates to a device for expressing pseudo-emotions of a pet type robot through voices, and particularly to a voice synthesis device, a pseudo-emotion expression device and a voice synthesizing method suited for transmitting distinctly each of a plurality of different pseudo-emotions to an observer.

2. Description of the Related Art

U.S. Pat. No. 6,175,772 (issued Jan. 16, 2001) discloses a robot pet having pseudo emotions and behaving based on the pseudo emotions. Behavior patterns of the pet robot change in accordance with a response from a user. Japanese patent laid-open No. 2000-187435 (published Apr. 7, 2000) discloses an information processing device comprising speech synthesis unit which retrieves speech data according to a response to a speech received and recognized by the device. Further, Japanese patent laid-open No. 11-126017 published May 11, 1999) and No. 10-328422 (published Dec. 15, 1998), for example, disclose interacting robots or toys. These robots are provided with pseudo-emotion generating systems, and their behavior is regulated according to their pseudo emotions. Other approaches to generate pseudo emotions have been reported (for example, Japanese patent laid-open No. 11-265239, published Sep. 28, 1999). The above conventional interacting robots are basically operated based on a threshold approach. That is, only when a value exceeds a given level, does the device activate a reaction. If a value is lower than the threshold level, no action is triggered.

However, in the conventional pseudo-emotion expression device, a voice is outputted based on the voice data corresponding to a pseudo-emotion with highest intensity of the pseudo-emotions generated by the pseudo-emotion generation section, so that no more than one pseudo-emotion generated by a pet type robot can be expressed at a time.

Regarding emotional expressions in human beings or animals, it is observed that when a plurality of emotions such as anger and delight occur simultaneously, an emotion with highest intensity of the emotions is mainly expressed. In this connection, it may be said that the conventional pseudo-emotion expression device generates emotional expressions relatively close to ones in human beings or animals. However, although in a pet type robot, closest possible features to an actual pet is intended to be materialized, the pet type robot has a certain limitation in that it is not an animal, but a robot after all. Thus, while a pet type robot with closest possible features is intended to be materialized, an attempt has been made at expressing attractiveness and cuteness not expected from an actual pet by providing the pet type robot with expressions specific thereto and different from the ones in the actual pet. For example, although the actual pet is not able to transmit distinctly each of a plurality of different emotions to an observer when it feels them simultaneously, if a pet type robot is developed capable of transmitting distinctly each of a plurality of pseudo-emotions to an observer, it will provide attractiveness and cuteness not expected from an actual pet.

In view of the foregoing unsolved problem of the prior art, it is an object of this invention to provide a voice synthesis device, a pseudo-emotion expression device and a voice synthesizing method suited for transmitting distinctly each of a plurality of different pseudo-emotions to an observer.

### SUMMARY OF THE INVENTION

The present invention can resolve the above problems. One embodiment of the present invention provides a sound synthesis device used for an interactive device which is capable of interacting with a user. The interactive device comprises a pseudo-emotion generator which is programmed to generate plural pseudo emotions based on signals received by the interaction device, said sound synthesis device comprising: (i) a sound data memory which stores a different sound assigned to each pseudo emotion; (ii) a sound signal generator which receives signals from the pseudo-emotion generator and accordingly generates a sound signal for each pseudo emotion by retrieving the sound data stored in the sound data memory; (iii) a sound synthesizer which is programmed to synthesize a sound by combining each sound signal from the sound signal generator, wherein the user can recognize overall emotions generated in the interaction device; and (iv) an output device which outputs a synthesized sound to the user. According to this embodiment, the user can recognize the interactive device's complex emotions, not only a representative emotion. The combination of sounds can be accomplished in various ways. For example, sounds which are distinct from each other are assigned to respective pseudo emotions, and according to the intensity of each pseudo emotion, sounds can be mixed and outputted. Types of sound are not restricted. For example, a sound of a flute is assigned to an emotion indicating “joyful”, and a sound of a drum is assigned to an emotion indicating “distasteful”. The user can sensorily recognize the mixed emotions of the device by listening the sounds. Sounds can be defined by frequencies, rhythms, melodies, tunes, notes, etc.

In the above, in an embodiment, the memory stores multiple sets of sound data. Each set defines sounds corresponding to pseudo emotions, and the sound signal generator further comprises a selection device which selects a set of sound data to be used based on a designated selection signal. For example, the designated selection signal may be a signal indicating the passage of time or may be a signal indicating the history of interaction between the user and the interactive device. According to this embodiment, the emotions expressed by the interactive device change over time or experience by selecting a different sound data sheet. For example, if the user plays with the device more than once in a day (this can be sensed easily by a touch sensor), a sound sheet designed for a moderate personality can be selected.

In the present invention, another aspect is an interactive device capable of interacting with a user, comprising: (a) a pseudo-emotion generator which is programmed to generate plural pseudo emotions based on signals received by the interaction device; and (b) the above-mentioned sound synthesis device.

A pseudo-emotion generating system is explained in U.S. Pat. No. 6,175,772 (issued Jan. 16, 2001), U.S. application Ser. No. 09/393,146 (filed Sep. 10, 1999) and Ser. No. 09/736,514 (filed Dec. 13, 2000), for example. A pseudo-personality generating system is disclosed in U.S. patent application Ser. No. 09/129,853 (filed Aug. 6, 1998), for example. A user recognition system is disclosed in U.S. patent application Ser. No. 09/630,577 (filed Aug. 3, 2000). These references are herein incorporated by reference.

Further, the present invention can be adopted equally to a method for synthesizing sounds for an interactive device which is capable of interacting with a user. The method comprises: (i) storing in a sound data memory a different sound assigned to each pseudo emotion; (ii) generating a sound signal for each pseudo emotion generated in the pseudo-emotion generator by retrieving the sound data stored in the sound data memory; (iii) synthesizing a sound by combining each sound signal generated for each pseudo emotion, wherein the user can recognize overall emotions generated in the pseudo-emotion generator; and (iv) outputting a synthesized sound to the user.

The present invention comprises other features as explained later.

For purposes of summarizing the invention and the advantages achieved over the prior art, certain objects and advantages of the invention have been described above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

Further aspects, features and advantages of this invention will become apparent from the detailed description of the preferred embodiments which follow.

### BRIEF DESCRIPTION OF THE DRAWINGS

These and other features of this invention will now be described with reference to the drawings of preferred embodiments which are intended to illustrate and not to limit the invention.

FIG. 1a is a schematic diagram showing an approach to express an emotion by sound.

FIG. 1b is a schematic diagram showing an approach to express an emotion by sound according to the present invention.

FIG. 2 is a block diagram showing the construction of a pet type robot 1.

FIG. 3 is a block diagram showing the construction of a user and environment recognition device 4i.

FIG. 4 is a block diagram showing an action determination device 4k.

FIG. 5 is a flow chart showing a voice data synthesizing procedure.

FIG. 6 is a flow chart showing a voice data synthesizing procedure.

The symbols in the figures denote as follows:

1: Pet type robot 2: External information input section

3: Internal information input section 4: Control section

4h: Storage information processing device

4i: User and environment information recognition device

4j: Pseudo-emotion generation device 4k: Action determination device

11: Action set selection device

12: Action set parameter setting device 13: Action reproduction device 14:

Voice data registration data base

15: Voice data synthesis device

4m: Characteristic action storage and processing device

4n: Character forming device 4p: Growing stage calculation device

5: Pseudo-emotion expression section

5a: Visual emotion expression device

5b: Auditory emotion expression device

5c: Tactile emotion expression device

### DETAILED DESCRIPTION OF THE PREFERRED EMBODIMENT

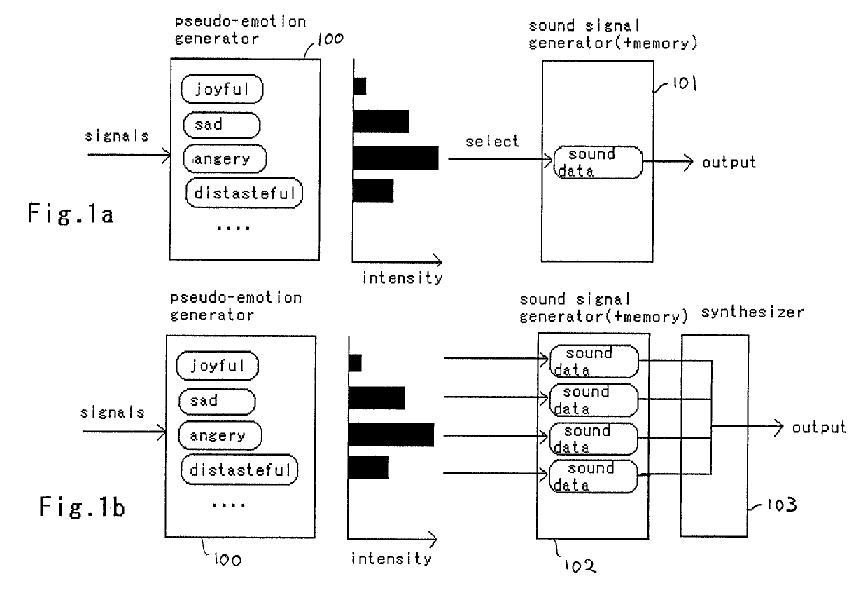

FIGS. 1a and 1b are schematic diagrams showing approaches to express an emotion formed in an interactive device. An interactive device equipped with a pseudo-emotion generator can have an emotion or emotions in response to external or internal circumstances. The device's behavior subroutine is subordinate to the pseudo emotions. These figures show communication with a user using sounds. According to emotion algorithms, a pseudo-emotion generator 100 generates emotions in response to signals such as signals indicating that the device has been touched roughly or an unrecognized person has touched the device. In these figures, “angry” has the highest intensity, but other emotions such as “sad” or “distasteful” are also indicated. In FIG. 1a, a sound data generator 101 possesses sound data corresponding to each emotion (which are retrieved from a memory). In this figure, only an “angry” emotion is expressed because the emotion is major and predominant. However, the user cannot know that the device is also sad while expressing anger. In contrast, in FIG. 1b, a sound signal generator 102 generates sound signals corresponding to respective emotions and outputs them to a synthesizer 103 to combine sounds. The user can hear not only a sound for anger but also a sound for sadness or distaste, thereby obtaining a better understanding of the device. The pseudo emotions expressed by the device are reflection of the user, and thus the user can more enjoy interaction with the device in FIG. 1b than in FIG. 1a.

The present invention further includes the following embodiments:

A voice synthesis device according to this invention of embodiment 1 is characterized by a voice synthesis device applied to a pseudo-emotion expression device which utilizes pseudo-emotion generation means for generating a plurality of different pseudo-emotions to express said plurality of pseudo-emotions through voices, wherein when voice data storage means is provided in which voice data is stored for each of said pseudo-emotions, voice data corresponding to each pseudo-emotion generated by said pseudo-emotion generating means is read from said voice data storage means and synthesized.

In the construction described above, with the voice data storage means being provided, voice data corresponding to each pseudo-emotion generated by the pseudo-emotion generation means is read from the voice data storage means and synthesized.

Here, voice data includes, for example, voice data in which voices of human beings or animals are recorded, musical data in which music is recorded, or sound effect data in which sound effect is recorded. The same is true for the voice synthesis device set forth in embodiment 2 explained below, the pseudo-emotion expression device set forth in embodiments 3, 4 (explained below), and the voice synthesizing method set forth in embodiment 9 (explained below).

The invention set forth in embodiment 1 can be applied not only to the pet type robot, but also, for example, to a virtual pet type robot implemented on a computer through software. In the former case, pseudo-emotion generation means may be utilized for generating a plurality of pseudo-emotions, for example, based on stimuli given from the outside, and in the latter case, pseudo-emotion generation means may be utilized for generating a plurality of pseudo-emotions, for example, based on the contents inputted into a computer by a user. The same is true for the voice synthesis device set forth in embodiment 2 and the voice synthesizing method set forth in embodiment 9.

Further, the voice synthesis device according to this invention of embodiment 2 is characterized by a device applied to a pseudo-emotion expression device which utilizes pseudo-emotion generation means for generating a plurality of different pseudo-emotions to express said plurality of pseudo-emotions through voices, said device comprising voice data storage means for storing voice data for each of said pseudo-emotions; and voice data synthesis means for reading from said voice data storage means and synthesizing voice data corresponding to each pseudo-emotion generated by said pseudo-emotion generation means.

In the construction described above, through the voice data synthesis means, voice data corresponding to each pseudo-emotion generated by the pseudo-emotion generation means is read from the voice data storage means and synthesized.

Here, the voice data storage means, which stores voice data by all possible means and at all times, may be one in which voice data has been stored in advance, or one in which in stead of the voice data being stored in advance, it is stored as input data from the outside during operation of this device. The same is true for the pseudo-emotion expression device set forth in embodiments 3, 4.

On the other hand, in order to achieve the foregoing object, the pseudo-emotion expression device according to this invention of embodiment 3 is characterized by a device for expressing a plurality of pseudo-emotions through voices, comprising voice data storage means for storing voice data for each of said pseudo-emotions; pseudo-emotion generation means for generating said plurality of pseudo-emotions; voice data synthesis means for reading from said voice data storage means and synthesizing voice data corresponding to each pseudo-emotion generated by said pseudo-emotion generation means; and voice output means for outputting a voice based on voice data synthesized by said voice data synthesis means.

In the construction described above, a plurality of pseudo-emotions are generated by the pseudo-emotion generation means, and through the voice data synthesis means, voice data corresponding to each pseudo-emotion generated is read from the voice data storage means and synthesized. A voice is outputted, based on the synthesized voice data, by the voice output means.

Here, the invention set forth in embodiment 3 can be applied not only to the pet type robot, but also, for example, to a virtual pet type robot implemented on a computer through software. In the former case, the pseudo-emotion generation means may generate a plurality of pseudo-emotions, for example, based on stimuli given from the outside, and in the latter case, the pseudo-emotion generation means may generate a plurality of pseudo-emotions, for example, based on the contents inputted into a computer by a user. The same is true for the pseudo-emotion expression device set forth in embodiment 4.

Furthermore, the pseudo-emotion expression device according to this invention of embodiment 4 is characterized by a device for expressing a plurality of pseudo-emotions through voices, comprising voice data storage means for storing voice data for each of said pseudo-emotions; stimulus recognition means for recognizing stimuli given from the outside; pseudo-emotion generation means for generating said plurality of pseudo-emotions based on the recognition result of said stimulus recognition means; voice data synthesis means for reading from said voice data storage means and synthesizing voice data corresponding to each pseudo-emotion generated by said pseudo-emotion generation means; and voice output means for outputting a voice based on voice data synthesized by said voice data synthesis means.

In the construction described above, if stimuli are given from the outside, they are recognized by the stimulus recognition means, a plurality of pseudo-emotions are generated, base on the recognition result by the pseudo-emotion generation means, and through the voice data synthesis means, voice data corresponding to each pseudo-emotion generated is read from the voice data storage means and synthesized. A voice is outputted, based on the synthesized voice data, by the voice output means.

Here, stimuli refer to not only ones that are perceivable by the five senses of human beings or animals, but also to ones that are detectable by detection means even if they are not perceivable by the five senses of human beings or animals. The stimulus recognition means may be provided, for example, with image input means such as a camera when recognizing stimuli perceivable by visual sensation of human beings or animals, and tactile detection means such as a pressure sensor or a tactile sensor when recognizing stimuli perceivable by tactile sensation of human beings or animals.

Moreover, the pseudo-emotion expression device according to this invention of embodiment 5 is characterized by the pseudo-emotion expression device of embodiment 3 or 4, further comprising character forming means for forming any of a plurality of different characters, wherein said voice data storage means is capable of storing, for each of said characters, a voice data correspondence table in which said voice data is registered corresponding to each of said pseudo-emotions; and said voice data synthesis means is adapted to read from said voice storage means and synthesize voice data corresponding to each pseudo-emotion generated by said pseudo-emotion generation means, by referring to a voice data correspondence table corresponding to a character formed by said character forming means.

In the construction described above, any of a plurality of different characters is formed by the character forming means, and through the voice data synthesis means, voice data corresponding to each pseudo-emotion generated by the pseudo-emotion expression means is read from the voice data storage means and synthesized, by referring to a voice data correspondence table corresponding to the formed character.

Here, the voice data storage means, which stores voice data correspondence tables by all possible means and at all times, may be one in which voice data correspondence tables have been stored in advance, or one in which in spite of the voice data correspondence tables being stored in advance, the voice data correspondence tables are stored as input information from the outside during operation of the device. The same is true for the pseudo-emotion expression device set forth in embodiment 6 or 7.

Yet further, the pseudo-emotion expression device according to this invention of embodiment 6 is characterized by the pseudo-emotion expression device of any of embodiments 3-5, further comprising growing stage specifying means for specifying growing stages, wherein said voice data storage means is capable of storing, for each of said growing stages, a voice data correspondence table in which said voice data is registered corresponding to each of said pseudo-emotions; and said voice data synthesis means is adapted to read from said voice storage means and synthesize voice data corresponding to each pseudo-emotion generated by said pseudo-emotion generation means, by referring to a voice data correspondence table corresponding to a growing stage specified by said growing stage specifying means.

In the construction described above, growing stages are specified by the growing stage specifying means, and through the voice data synthesis means, voice data corresponding to each pseudo-emotion generated by the pseudo-emotion expression means is read from the voice data storage means and synthesized, by referring to a voice data correspondence table corresponding to the specified growing stage.

Further, a pseudo-emotion expression device according to this invention of embodiment 7 is characterized by the pseudo-emotion expression device of any of embodiments 3-6, wherein said voice data storage means is capable of storing a plurality of voice data correspondence tables in which said voice data is registered corresponding to each of said pseudo-emotions; table selection means is provided for selecting any of said plurality of voice data correspondence tables; and said voice data synthesis means is adapted to read from said voice storage means and synthesize voice data corresponding to each pseudo-emotion generated by said pseudo-emotion generation means, by referring to a voice data correspondence table selected by said table selection means.

In the construction described above, when any of the plurality of voice data correspondence tables is selected by the selection means, then through the voice data synthesis means, voice data corresponding to each pseudo-emotion generated by the pseudo-emotion expression means is read from the voice data storage means and synthesized, by referring to the selected voice data correspondence table.

Here, the selection means may be adapted to select the voice data correspondence table by hand, or based on random numbers or a given condition.

Still further, the pseudo-emotion expression device according to this invention of embodiment 8 is characterized by the pseudo-emotion expression device of embodiments 3-7, wherein said pseudo-emotion generation means is adapted to generate the intensity of each of said pseudo-emotions; and said voice data synthesis means is adapted to produce an acoustic effect equivalent to the intensity of the pseudo-emotion generated by said pseudo-emotion generation means and synthesize said voice data.

In the construction described above, the intensity of each pseudo-emotion is generated by the pseudo-emotion generation means, and through the voice data synthesis means, an acoustic effect equivalent to the intensity of the generated pseudo-emotion is given to the read-out voice data and the voice data is synthesized.

Here, the acoustic effect refers to one that changes voice data such that the voice outputted based on the voice data is changed before and after the acoustic effect is given, and includes, for example, an effect of changing the volume of the voice, an effect of changing the frequency of the voice, or an effect of changing the pitch of the voice.

On the other hand, in order to achieve the foregoing object, the voice synthesizing method according to this invention of embodiment 9 is characterized by a voice synthesizing method applied to a pseudo-emotion expression device which utilizes pseudo-emotion generation means for generating a plurality of different pseudo-emotions to express said plurality of pseudo-emotions through voices, wherein when voice data storage means is provided in which voice data is stored for each of said pseudo-emotions, voice data corresponding to each pseudo-emotion generated by said pseudo-emotion generating means is read from said voice data storage means and synthesized.

Here, in order to achieve the foregoing object, the following voice synthesizing methods and pseudo-emotion expressing methods may be specifically be suggested.

The first voice synthesizing method is characterized by a method that may be applied to a pseudo-emotion expression device which utilizes pseudo-emotion generation means for generating a plurality of different pseudo-emotions to express said plurality of pseudo-emotions through voices, said method including steps of storing voice data for each of said pseudo-emotions to voice data storage means, and reading from said voice data storage means and synthesizing voice data corresponding to each pseudo-emotion generated by said pseudo-emotion generation means.

With the method described above, the same effect as in the voice synthesis device of embodiment 2 can be achieved.

Here, the first voice synthesizing method may be applied not only to the pet type robot, but also, for example, to a virtual pet type robot implemented on a computer through software. In the former case, pseudo-emotion generation means may be utilized for generating a plurality of pseudo-emotions, for example, based on stimuli given from the outside, and in the latter case, pseudo-emotion generation means may be utilized for generating a plurality of pseudo-emotions, for example, based on the contents inputted into a computer by a user.

On the other hand, the first pseudo-emotion expressing method is characterized by a method for expressing a plurality of pseudo-emotions through voices, including steps of storing voice data for each of said pseudo-emotions to the voice data storage means, generating said plurality of pseudo-emotions, reading from said voice data storage means and synthesizing voice data corresponding to each pseudo-emotion generated at said pseudo-emotion generating step, and outputting a voice based on voice data synthesized at said voice data synthesizing step.

With the method described above, the same effect as in the pseudo-emotion expression device of embodiment 3 can be achieved.

Here, the first pseudo-emotion expressing method can be applied not only to the pet type robot, but also, for example, to a virtual pet type robot implemented on a computer through software. In the former case, at the pseudo-emotion generating step are generated a plurality of pseudo-emotions, for example, based on stimuli given from the outside, and in the latter case, at the pseudo-emotion generating step are generated a plurality of pseudo-emotions, for example, based on the contents inputted into a computer by a user.

Further, the second pseudo-emotion expressing method is characterized by a method of expressing a plurality of pseudo-emotions through voices, including steps of storing voice data for each of said pseudo-emotions to the voice data storage means, recognizing stimuli given from the outside, generating said plurality of pseudo-emotions based on the recognition result of said stimulus recognizing step, reading from said voice data storage means and synthesizing voice data corresponding to each pseudo-emotion generated at said pseudo-emotion generating step, and outputting a voice based on voice data synthesized at said voice data synthesizing step.

With the method described above, the same effect as in the pseudo-emotion expression device of embodiment 4 can be achieved.

Here, the stimuli have the same definition as in the pseudo-emotion expression device of embodiment 4.

Furthermore, the third pseudo-emotion expressing method is characterized by either of the first and the second pseudo-emotion expressing method, further including a step of forming any of a plurality of different characters, wherein at said voice data storing step is stored, for each of said characters in said voice data storage means, a voice data correspondence table in which said voice data is registered corresponding to each of said pseudo-emotions, and at said voice data synthesizing step is read from said voice storage means and synthesized voice data corresponding to each pseudo-emotion generated at said pseudo-emotion generating step, by referring to a voice data correspondence table corresponding to a character formed at said character forming step.

With the method described above, the same effect as in the pseudo-emotion expression device of embodiment 5 can be achieved.

Moreover, the fourth pseudo-emotion expressing method is characterized by any of the first through the third pseudo-emotion expressing method, further including a step of specifying growing stages, wherein at said voice data storing step is stored, for each of said growing stages in said voice data storage means, a voice data correspondence table in which said voice data is registered corresponding to each of said pseudo-emotions, and at said voice data synthesizing step is read from said voice storage means and synthesized voice data corresponding to each pseudo-emotion generated at said pseudo-emotion generating step, by referring to a voice data correspondence table corresponding to a growing stage specified at said growing stage specifying step.

With the method described above, the same effect as in the pseudo-emotion expression device of embodiment 6 can be achieved.

Furthermore, the fifth pseudo-emotion expressing method is characterized by any of the first through the fourth pseudo-emotion expressing method, wherein at said voice data storing step are stored, in said voice data storage means, a plurality of voice data correspondence tables in which said voice data is registered corresponding to each of said pseudo-emotions, a step is included of selecting any of said plurality of voice data correspondence tables, and at said voice data synthesizing step is read from said voice storage means and synthesized voice data corresponding to each pseudo-emotion generated at said pseudo-emotion generating step, by referring to a voice data correspondence table selected at said table selecting step.

With the method described above, the same effect as in the pseudo-emotion expression device of embodiment 7 can be achieved.

Here, at the selecting step may be selected the voice data correspondence table by hand, or based on random numbers or a given condition.

Yet further, the sixth pseudo-emotion expressing method is characterized by any of the first through fifth pseudo-emotion expressing method, wherein at said pseudo-emotion generating step is generated the intensity of each of said pseudo-emotions, and at said voice data synthesizing step is produced an acoustic effect equivalent to the intensity of the pseudo-emotion generated at said pseudo-emotion generating step and synthesized said voice data.

With the method described above, the same effect as in the pseudo-emotion expression device of embodiment 8 can be achieved.

Here, the acoustic effect has the same definition as in the pseudo-emotion expression device of embodiment 8.

In the description above, voice synthesis devices, pseudo-emotion expression devices and voice synthesizing methods have been suggested to achieve the foregoing object, but in addition to these devices, the following storage medium can also be suggested.

This storage medium is characterized by a computer readable storage medium for storing a pseudo-emotion expression program for expressing a plurality of different pseudo-emotions through voices, wherein a program is stored for executing processing implemented by pseudo-emotion generation means for generating said plurality of pseudo-emotions, voice data synthesis means for reading from said voice data storage means and synthesizing voice data corresponding to each pseudo-emotion generated by said pseudo-emotion generation means, and voice output means for outputting a voice based on voice data synthesized by said voice data synthesis means, on a computer with voice data storage means for storing voice data on each of said pseudo-emotions.

In the construction described above, when the pseudo-emotion expression program stored in the storage medium is read by a computer and the computer runs according to the read-out program, the same function and effect as in the pseudo-emotion expression device of embodiment 3 can be achieved.

### EXAMPLE

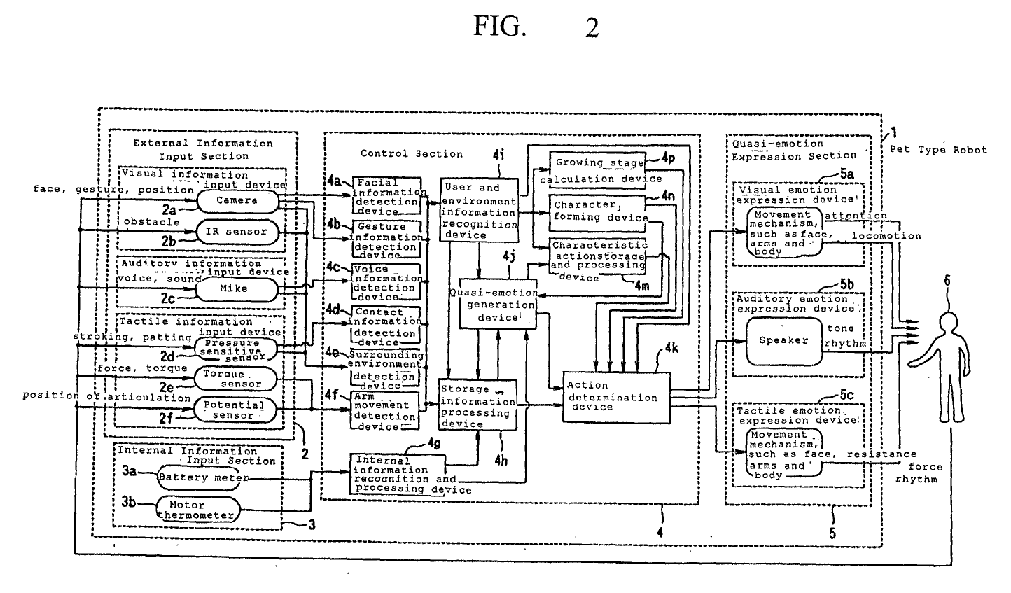

Now, an embodiment will be described with reference to the drawings. FIG. 2-FIG. 6 illustrate an embodiment of a voice synthesis device, a pseudo-emotion expression device and a voice synthesizing method according to this invention.

In this embodiment, the voice synthesis device, the pseudo-emotion expression device and the voice synthesizing method according to this invention are applied to a case where a plurality of different pseudo-emotions generated by a pet type robot 1 are expressed through voices, as shown in FIG. 2.

First, the construction of the pet type robot 1 will be described by referring to FIG. 2, which is a block diagram of the same.

The pet type robot 1, as shown in FIG. 2, is comprised of an external information input section 2 for inputting external information on stimuli, etc given from the outside; an internal information input section 3 for inputting internal information obtained within the pet type robot 1; a control section 4 for controlling pseudo-emotions or actions of the pet type robot 1; and a pseudo-emotion expression section 5 for expressing pseudo-emotions or actions of the pet type robot 1 based on the control result of the control section 4.

The external information input section 2 comprises, as visual information input devices, a camera 2a for detecting user 6's face, gesture, position, etc, and an IR (infrared) sensor 2b for detecting surrounding obstacles; as an auditory information input device, a mike 2c for detecting user 6's utterance or ambient sounds; and further, as tactile information devices, a pressure sensitive sensor 2d for detecting stroking or patting by the user 6, a torque sensor 2e for detecting forces and torques in legs or forefeet of the pet type robot 1, and a potential sensor 4f for detecting positions of articulations of legs and forefeet of the pet type robot 1. The information from these sensors 2a-2f is outputted to the control section 4.

The internal information input section 3 comprises a battery meter 3a for detecting information on hunger of the pet type robot 1, and a motor thermometer 3b for detecting information on fatigue of the pet type robot 1. The information from these sensors 3a, 3b is outputted to the control section 4.

The control section 4 comprises a facial information detection device 4a and a gesture information detection device 4b for detecting facial information on the user 6 from signals of the camera 2a; a voice information detection device 4c for detecting voice information on the user 6 from signals of the mike 2c; a contact information detection device 4d for detecting tactile information on the user 6 from signals from the pressure sensitive sensor 2d; an environment detection device 4e for detecting environments from signals of the camera 2a, IR sensor 2b, mike 2c and pressure sensitive sensor 2d; and a movement detection device 4f for detecting movements and resistance forces of arms of the pet type robot 1 from signals of the torque sensor 2c and potential sensor 2f. It further comprises an internal information recognition and processing device 4g for recognizing internal information based on information from the internal information input section 3; a storage information processing device 4h; a user and environment information recognition device 4i; a pseudo-emotion generation device 4j; an action determination device 4k; a character forming device 4n; and a growing stage calculation device 4p.

The internal information recognition and processing device 4g is adapted to recognize internal information on the pet type robot 1 based on signals from the battery meter 3a and the motor thermometer 3b, and to output the recognition result to the storage information processing device 4h and the pseudo-emotion generation device 4j.

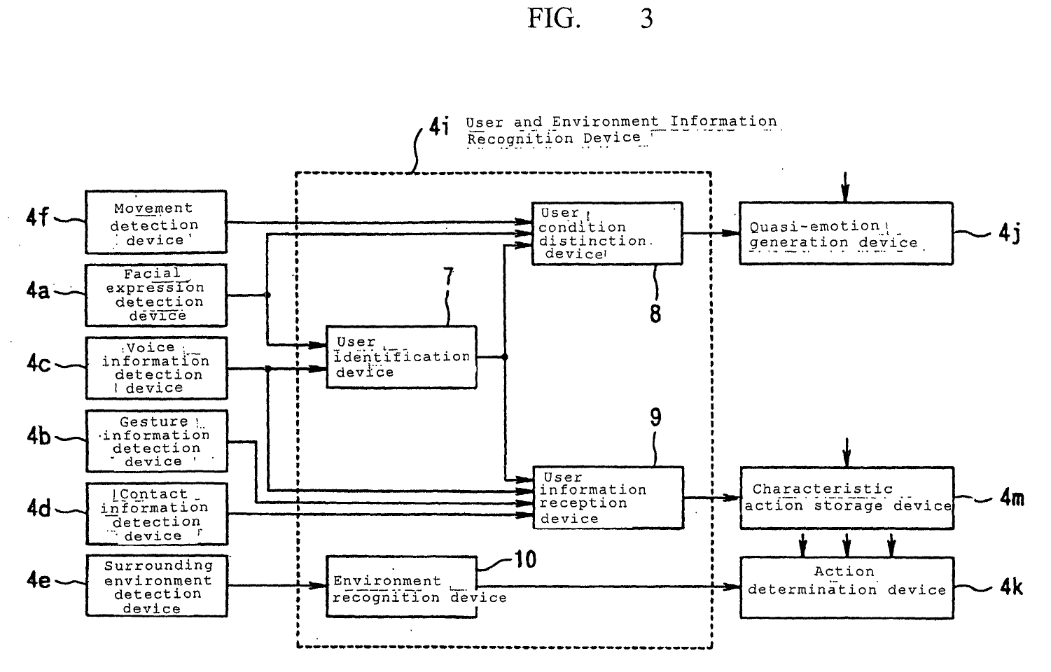

Now, the construction of the pet type robot 1 will be described in detail by referring to FIG. 3, which is a block diagram of the same.

The user and environment recognition device 4i, as shown in FIG. 3, comprises a user identification device 7 for identifying the user 6, a user condition distinction device 8 for distinguishing user conditions, a reception device 9 for receiving information on the user 6, and an environment recognition device 10 for recognizing surrounding environments.

The user identification device 7 is adapted to identify the user 6 based on the information from the facial information detection device 4a and the voice information detection device 4c, and to output the identification result to the user condition distinction device 8 and the reception device 9.

The user condition distinction device 8 is adapted to distinguish user 6's conditions based on the information from the facial information detection device 4a, the movement detection device 4f and the user identification device 7, and to output the distinction result to the pseudo-emotion generation device 4j.

The reception device 9 is adapted to input information separately from the gesture information detection device 4b, the voice information detection device 4c, the contact information detection device 4d and the user identification device 7, and to output the received information to a characteristic action storage device 4m.

The environment recognition device 10 is adapted to recognize surrounding environments based on the information from the environment detection device 4e, and to output the recognition result to the action determination device 4k.

Referring again to FIG. 2, the pseudo-emotion generation device 4j is adapted to generate a plurality of different pseudo-emotions of the pet type robot 1 based on the information from the user condition distinction device 8 and pseudo-emotion models in the storage information processing device 4h, and to output them to the action determination device 4k and the characteristic action storage and processing device 4m. Here, the pseudo-emotion models are calculation formulas used for finding parameters, such as sorrow, delight, fear, hatred, fatigue, hunger and sleepiness, expressing pseudo-emotions of the pet type robot 1, and generate pseudo-emotions of the pet type robot 1 in response to the user information (user 6's temper or command) detected as voices or images and environmental information (lightness of the room or sound, etc). Generation of the pseudo-emotions is performed by generating the intensity of each pseudo-emotion. For example, when the user 6 appears in front of the robot, a pseudo-emotion of “delight” is emphasized by generating the pseudo-emotion such that the intensity of the pseudo-emotion of “delight” is “5” and that of a pseudo-emotion of “anger” is “0,” and on the contrary, when a foreigner appears in front of the robot, the pseudo-emotion of “anger” is emphasized by generating the pseudo-emotion such that the intensity of the pseudo-emotion of “delight” is “0” and that of the pseudo-emotion of “anger” is “5.”

The character forming device 4n is adapted to form the character of the pet type robot 1 into any of a plurality of different characters, such as “a quick-tempered one,” “a cheerful one” and “a gloomy one,” based on the information from the user and environment recognition device 4i, and to output the formed character of the pet type robot 1 as character data to the pseudo-emotion generation device 4j and the action determination device 4k.

The growing stage calculation device 4p is adapted to change the pseudo-emotions of the pet type robot 1 through praising and scolding by the user, based on the information from the user and environment information recognition device 4j, to allow the pet type robot 1, and to output the growth result as growth data to the action determination device 4k. The pseudo-emotion models are prepared such that the pet type robot 1 moves childish when very young and moves matured as it grows. The growing process is specified, for example, as three stages of “childhood,” “youth” and “old age.”

The characteristic action storage and processing device 4m is adapted to store and process characteristic actions such as actions through which the pet type robot 1 becomes tame gradually with the user 6, or actions of learning user 6's gestures, and to output the processed result to the action determination device 4k.

On the other hand, the pseudo-emotion expression section 5 comprises a visual emotion expression device 5a for expressing pseudo-emotions visually, an auditory emotion expression device 5b for expressing pseudo-emotions auditorily, and a tactile emotion expression device 5c for expressing pseudo-emotions tactilely.

The visual emotion expressing device 5a is adapted to drive movement mechanisms such as the face, arms and body of the pet type robot 1, based on action set parameters from an action set parameter setting device 12 (described later), and through the device 5a, the pseudo-emotions of the pet type robot 1 are transmitted to the user 6 as attention or locomotion information (for example, facial expression, nodding or dancing). The movement mechanisms may be, for example, actuators such as a motor, an electromagnetic solenoid, and a neumatic or hydraulic cylinder.

The auditory emotion expression device 5b is adapted to output voices by driving a speaker, based on voice data synthesized by a voice data synthesis device 15 (described later), and through the device 5b, the pseudo-emotions of the pet type robot 1 are transmitted to the user 6 as tone or rhythm information (for example, cries).

The tactile emotion expression device 5c is adapted to drive the movement mechanisms such as the face, arms and body, based on the action set parameters from the action set parameter setting device 12, and the pseudo-emotions of the pet type robot 1 are transmitted to the user 6 as resistance force or rhythm information (for example, tactile sensation received by the user 6 when the robot performs a trick of “hand up”). The movement mechanisms may be, for example, actuators such as a motor, an electromagnetic solenoid, and a neumatic or hydraulic cylinder.

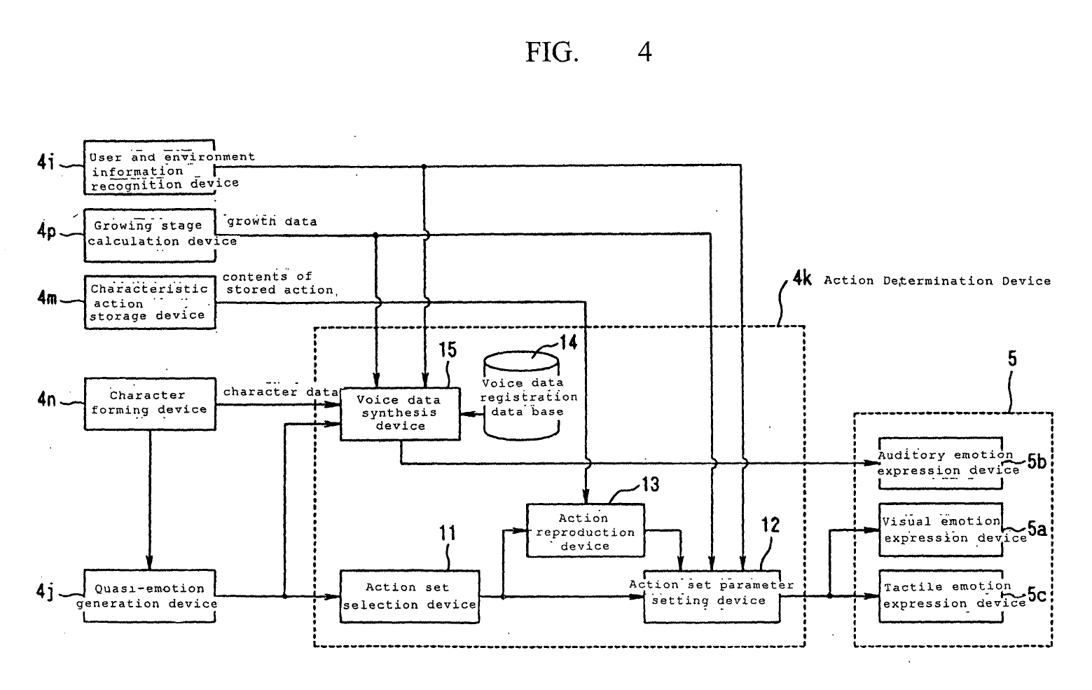

Now, the construction of the action determination device 4k will be described by referring to FIG. 4, which is a block diagram of the same.

The action determination device 4k, as shown in FIG. 4, comprises an action set selection device 11, an action set parameter setting device 12, an action reproduction device 13, a voice data registration data base 14 with voice data stored for each pseudo-emotion, and a voice data synthesis device 15 for synthesizing voice data of the voice data registration data base.

The action set selection device 11 is adapted to determine a fundamental action of the pet type robot 1 based on the information from the pseudo-emotion generation device 4j, by referring to an action set (action library) of the storage information processing device 4h, and to output the determined fundamental action to the action set parameter setting device 12. In the action library, sequences of actions are registered for specific expression of the pet type robot 1, for example, a sequence of actions of “moving each leg in a predetermined order” for the action pattern of “advancing,” and a sequence of actions of “folding the hind legs in a sitting posture and put forelegs up and down alternately” for the action pattern of “dancing.”

The action reproduction device 13 is adapted to correct an action set of the action set selection device 11 based on the action set of the characteristic action storage device 4m, and to output the corrected action set to the action set parameter setting device 12.

The action set parameter setting device 12 is adapted to set action set parameters such as the speed at which the pet type robot 1 approaches the user 6, for example, the resistance force when it grips the user 6's hand, etc, and to output the set action set parameters to the visual emotion expressing device 5a and the tactile emotion expression device 5c.

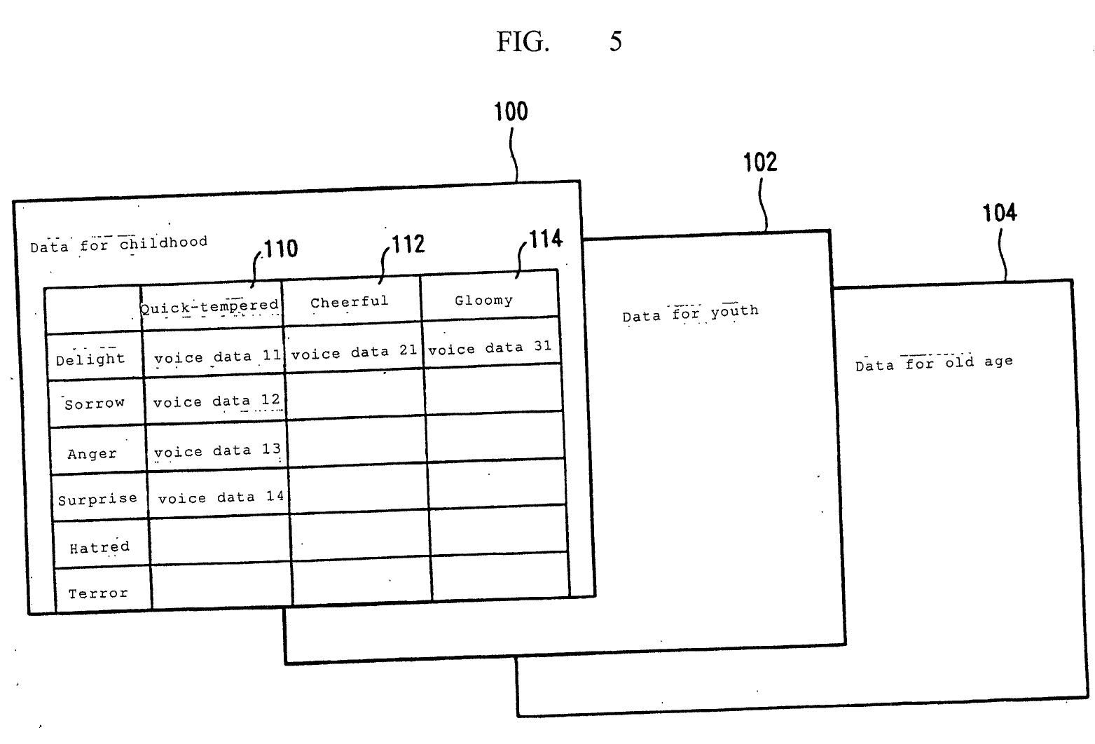

The voice data registration data base 14, as shown in FIG. 5, contains a plurality of voice data pieces, and voice data correspondence tables 100-104 in which voice data is registered corresponding to each pseudo-emotion, one for each growing stage. FIG. 5 is a diagram showing the data structure of the voice data correspondence tables.

The voice data correspondence table 100, as shown in FIG. 5, is a table which is to be referred to when the growing stage of the pet type robot 1 is in “childhood,” and in which are registered records, one for each pseudo-emotion. These records are arranged such that they include a field 110 for voice data pieces 1i (i represents a record number) which are to be outputted when the character of the pet type robot 1 is “quick-tempered,” a field 112 for voice data pieces 2i which are to be outputted when the character of the pet type robot 1 is “cheerful,” and a field 114 for voice data pieces 3i which are to be outputted when the character of the pet type robot 1 is “gloomy.”

The voice data correspondence table 102 is a table which is to be referred to when the growing stage of the pet type robot 1 is in “youth,” in which are registered records, one for each pseudo-emotion. These records, like the records of the voice correspondence table 100, are arranged such that they include fields 110-114.

The voice data correspondence table 104 is a table which is to be referred to when the growing stage of the pet type robot 1 is in “old age,” in which are registered records, one for each pseudo-emotion. These records, like the records of the voice correspondence table 100, are arranged such that they include fields 110-114.

That is, by referring to the voice data reference tables 100-104, voice data to be outputted for each pseudo-emotion can be identified in response to the growing stage and the character of the pet type robot 1. In the example of FIG. 5, the growing stage of the pet type robot 1 is in “childhood,” so that when its character is “cheerful,” it is seen that music data 11 may be read for the pseudo-emotion of “delight,” and music data 12 for the pseudo-emotion of “sorrow,” and music data 13 for the pseudo-emotion of “anger.”

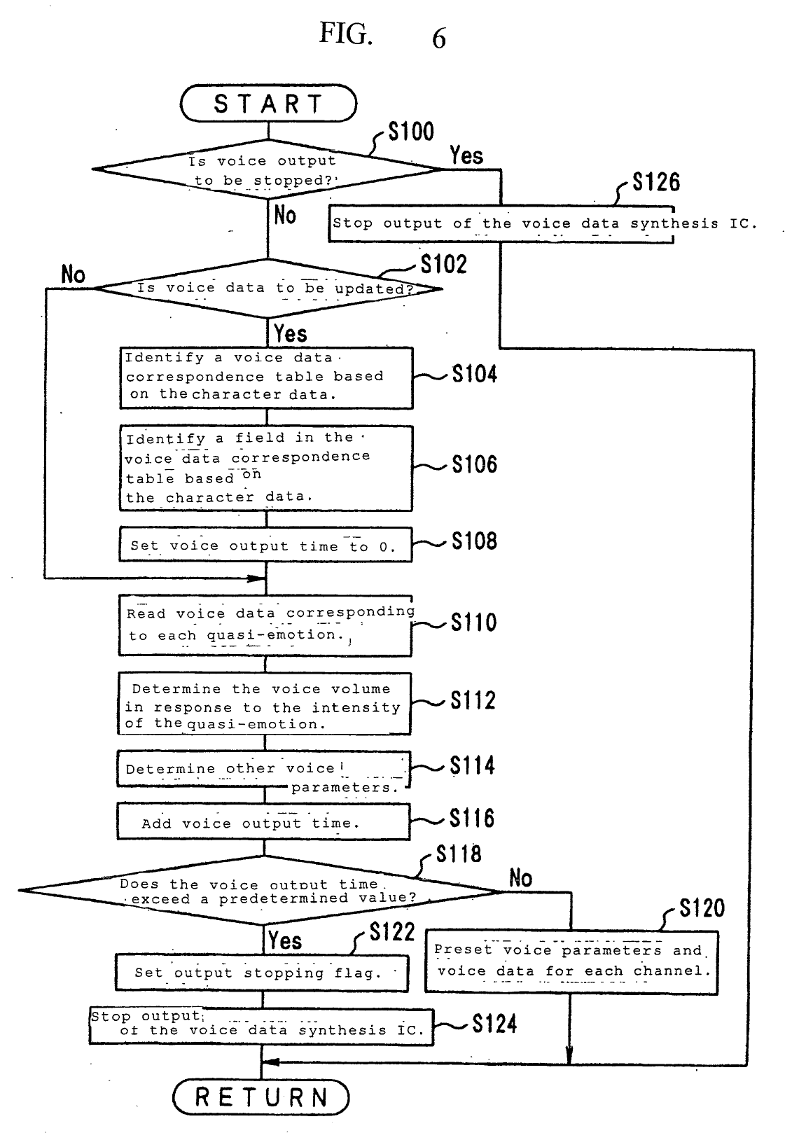

Now, the construction of the voice data synthesis device 15 will be described by referring to FIG. 6.

The voice data synthesis device 15 is comprised of a CPU, a ROM, a RAM, an I/F, etc connected by bus, and further includes a voice data synthesis IC having a plurality of channels for synthesizing and outputting voice data preset for each channel.

The CPU of the voice data synthesis device 15 is made of a microprocessing unit, etc, and adapted to start a given program stored in a given region of the ROM and to execute voice data synthesis processing shown by the flow chart in FIG. 6 by interruption at given time intervals (for example, 100 ms) according to the program. FIG. 6 is a flow chart showing the voice data synthesis procedure.

The voice data synthesis procedure is one through which voice data corresponding to each pseudo-emotion generated by the pseudo-emotion generation device 4j is read from the voice data registration data base 14 and synthesized, based on the information from the user and environment information recognition device 4i, the pseudo-emotion generation device 4j, the character forming device 4n and the growing stage calculation device 4p, and when executed by the CPU, first, as shown in FIG. 6, the procedure proceeds to step S100.

At step S100, after determined whether or not a voice stopping command has been entered from the control device 4, etc, it is determined whether or not voice output is to be stopped. If it is determined that the voice output is not stopped (No), the procedure proceeds to step S102, where it is determined whether or not voice data is to be updated, and if it is determined that the voice data is updated (Yes), the procedure proceeds to step S104.

At step S104, one of the voice data correspondence tables 100-106 is identified, based on the growth data from the growing stage calculation device 4p, and the procedure proceeds to step S106, where a field from which the voice data is read, is identified from among the fields in the voice data correspondence table identified at step S104, based on the character data from the character forming device 4n. Then, the procedure proceeds to step S108.

At step S108, voice output time necessary to measure the length of time that has elapsed from the start of the voice output, is set to “0,” and the procedure proceeds to step S110, where voice data corresponding to each pseudo-emotion generated by the pseudo-emotion generation device 4j is read from the voice data registration data base 14, by referring to the field identified at step S106 from among the fields in the voice data correspondence table identified at step S104. Then, the procedure proceeds to step S112.

At step S112, a volume parameter of the voice volume is determined such that the read-out voice data has the voice volume in response to the intensity of the pseudo-emotion generated by the pseudo-emotion generation device 4j, and the procedure proceeds to step S114, where other parameters for specifying the total volume, tempo or other acoustic effects are determined. Then, the procedure proceeds to step S116, where voice output time is added, and to step S118.

At step S118, it is determined whether or not the voice output time exceeds a predetermined value (upper limit of the output time specified for each voice data piece), and if it is determined that the voice output time is less than the predetermined value (No), the procedure proceeds to step S120, where the determined voice parameters and the read-out voice data are preset for each channel in the voice data synthesis IC. A series of processes is then completed and the procedure is returned to the original processing.

On the other hand, at step S118, if it is determined that the voice output time is exceeds a predetermined value (Yes), the procedure proceeds to step S122, where an output stopping flag is set indicative of whether or not the voice output is to be stopped, and the procedure proceeds to step S124, where a stopping command to stop the voice output is outputted to the voice data synthesis IC to thereby stop the voice output. Then a series of processes is completed and the procedure is returned to the original processing.

On the other hand, at step S102, if it is determined that the voice data is not updated (No), the procedure proceeds to step S110.

At step S110, if it is determined that the voice output is stopped (Yes), the procedure proceeds to step S126, where a stopping command to stop the voice output is outputted to the voice data synthesis IC to thereby stop the voice output. Then, a series of processes is completed and the procedure is returned to the original processing.

Now, operation of the foregoing embodiment will be described.

When stimuli are given to the pet type robot 1 by a user stroking or speaking, for example, to the robot, the stimuli are recognized by the sensors 2a-2f, the detection devices 4a-4f and the user and environment information recognition device 4i, and the intensity of each pseudo-emotion is generated by the pseudo-emotion generation device 4j, based on the recognition result. For example, if it is assumed that the robot has pseudo-emotions of “delight,” “sorrow,” “anger,” “surprise,” “hatred” and “terror,” the intensity of each pseudo-emotion is generated as having the grades of “5,” “4,” “3,” “2” and “1.”

On the other hand, as the pet type robot 1 learns the amount of stimuli or stimulus patterns given from the user 6 as a result of, for example, praising or scolding by the user 6, the character of the pet type robot 1 is formed by the character forming device 4n into any of a plurality of characters such as “a quick-tempered one,” “a cheerful one” and “a gloomy one,” based on the information from the user and environment recognition device 4i, and the formed character is outputted as character data. Also, the pseudo-emotions of the pet type robot 1 are changed by the growing stage calculation device 4p to allow the pet type robot 1 to grow, based on the information from the user and environment information recognition device 4j, and the growth result is outputted as growth data. The growing process changes through three stages of “childhood,” “youth” and “old age” in this order.

When the intensity of each pseudo-emotion, growth data and character data are thus generated, one of the voice data correspondence tables 100-106 is identified by the voice data synthesis device 15 at steps S104-S106, based on the growth data from the growing stage calculation device 4p, and a field from which voice data is read, is identified from among the fields in the identified voice data correspondence table, based on the character data from the character forming device 4n. For example, if the growing stage is in “childhood” and the character is “quick-tempered,” the voice correspondence table 100 is identified as a voice data correspondence table, and the field 100 as a field from which voice data is read.

Then, at steps S108-112, voice data corresponding to each pseudo-emotion generated by the pseudo-emotion generation device 4j is read from the voice data registration data base 14, by referring to the field identified from among the fields in the identified voice data correspondence table, and a voice parameter of the voice volume is determined such that the read-out voice data has the voice volume in response to the intensity of the pseudo-emotion generated by the pseudo-emotion generation device 4j.

Then, at steps S108-S120, the determined voice parameter and readout voice data are preset for each channel in the voice data synthesis IC, and voice data is synthesized by the voice data synthesis IC, based on the preset voice parameter, to be outputted to the auditory emotion expression device 5c.

Voices are outputted by the auditory emotion expression device 5c, based on the voice data synthesized by the voice data synthesis device 15.

That is, in the pet type robot 1, when a pseudo-emotion is expressed, voice data corresponding to each pseudo-emotion is synthesized and a voice is outputted with the voice volume in response to the intensity of each pseudo-emotion. For example, if a pseudo-emotion of “delight” is strong, the voice corresponding to the pseudo-emotion of “delight” of output voices is outputted with relatively large volume, and if a pseudo-emotion of “anger” is strong, the voice corresponding to the pseudo-emotion of “anger” is outputted with relatively large volume.

In this embodiment as described above, stimuli given from the outside are recognized; a plurality of pseudo-emotions are generated, based on the recognition result; voice data corresponding to each pseudo-emotion generated is read from the voice data registration data base 14 and synthesized; and a voice is outputted, based on the synthesized voice data.

Therefore, a voice corresponding to each pseudo-emotion is synthesized to be outputted, so that each of a plurality of different pseudo-emotions can be transmitted relatively distinctly to a user. Thus, attractiveness and cuteness not expected from an actual pet can be expressed.

Further, in this embodiment, the character of the pet type robot 1 is formed into any of a plurality of different characters; and voice data corresponding to each pseudo-emotion generated is read from the voice data registration data base 14 and synthesized, by referring to a field corresponding to the formed character of the fields in the voice data correspondence table.

Therefore, a different synthesized voice is outputted for each character, so that each of a plurality of different characters can be transmitted relatively distinctly to a user. Thus, attractiveness and cuteness not expected from an actual pet can be expressed further.

Furthermore, in this embodiment, growing stages of the pet type robot 1 are specified; and voice data corresponding to each pseudo-emotion generated is read from the voice data registration data base 14 and synthesized, by referring to a voice data correspondence table corresponding to the specified growing stage.

Therefore, a different synthesized voice is outputted for each growing stage, so that each of a plurality of growing stages can be transmitted relatively distinctly to a user. Thus, attractiveness and cuteness not expected from an actual pet can be expressed further.

Moreover, in this embodiment, the intensity of each pseudo-emotion is generated; and the read-out voice data is synthesized such that it has the voice volume in response to the intensity of the generated pseudo-emotion.

Therefore, the intensity of each of a plurality of different pseudo-emotions can be transmitted relatively distinctly to a user. Thus, attractiveness and cuteness not expected from an actual pet can be expressed further.

In the foregoing embodiment, the voice data registration data base 14 corresponds to the voice data storage means of embodiments 1-6, or 9; the pseudo-emotion generation device 4j to the pseudo-emotion generation means of embodiments 1-6, or 8 or 9; the voice data synthesis device 15 to the voice data synthesis means of embodiments 2-6, or 8; and the auditory emotion expression device 5b to the voice output means of embodiment 3 or 4. The sensors 2a-2f, the detection devices 4a-4f and the user and environment information recognition device 4i correspond to the stimulus recognition means of embodiment 4; the character forming device 4n to the character forming means of embodiment 5; and the growing stage calculation device 4p to the growing stage specifying means of embodiment 6.

Although in the foregoing embodiment, a different synthesized voice is outputted for each character or each growing stage, this invention is not limited to that, but may be arranged such that a switch for selecting the voice data correspondence table is provided at a position accessible to a user for switching, and voice data corresponding to each pseudo-emotion generated is read from the voice data registration data base 14 and synthesized, by referring to the voice data correspondence table selected by the switch.

Therefore, a different synthesized voice is outputted for each switching condition, so that attractiveness and cuteness not expected from an actual pet can be expressed further.

In addition, although in the foregoing embodiment, voice data is stored in the voice data registration data base 14 in advance, this invention is not limited to that, but voice data downloaded from the internet, etc, or voice data read from a portable storage medium, etc, may be registered in the voice data registration data base 14.

Further, although in the foregoing embodiment, the contents of the voice data correspondence tables 100-102 are registered in advance, this invention is not limited to that, but they may be registered and compiled a discretion of a user.

Furthermore, although in the foregoing embodiment, the read-out voice data is synthesized such that it has the voice volume in response to the intensity of the generated pseudo-emotion, this invention is not limited to that, but may be arranged such that an effect is given, for example, of changing the voice frequency or the voice pitch in response to the intensity of the generated pseudo-emotion.

Moreover, although in the foregoing embodiment, emotions of the user are not considered specifically in synthesizing voices, this invention is not limited to that, voice data may be synthesized, based on the information from the user condition recognition device 8. For example, if it is recognized that the user is in a good tamper, movement may be accelerated to produce a light feeling, or on the contrary, if it is recognized that the user is not in a good temper, total voice volume is decreased to keep quiet conditions.

Further, although in the foregoing embodiment, surrounding environments are not considered specifically in synthesizing voices, this invention is not limited to that, voice data may be synthesized, based on the information from the environment recognition device 10. For example, if it is recognized that it is light in the surrounding environment, movement may be accelerated to produce a light feeling, or if it is recognized that it is calm in the surrounding environment, total voice volume is decreased to keep quiet conditions.

Further, although in the foregoing embodiment, operation to stop the voice output is not described specifically, voice output may be stopped or resumed in response to stimuli given from the outside, for example, by a voice stopping switch provided in the pet type robot 1. Furthermore, although in the foregoing embodiment, three growing stages are specified, this invention is not limited to that, but two stages, or four or more stages may be specified. If growing stages increase in number or have a continuous value, a great number of voice data correspondence tables must be prepared, which increases the memory occupancy ratio. In such a case, voice data may be identified using a given calculation formula based on the growing stage, or voice data to be synthesized is given a certain acoustic effect based on the growing stage, using a given calculation formula.

Further, although in this embodiment, characters of the pet type robot 1 are divided into three categories, this invention is not limited to that, but they may be divided into two, or four or more categories. If characters of the pet type robot 1 increase in number or have a continuous value, a great number of voice data correspondence tables must be prepared, which increases the memory occupancy ratio. In such a case, voice data may be identified using a given calculation formula based on the growing stage, or voice data to be synthesized may be given a certain acoustic effect based on the growing stage, using a given calculation formula.

Further, although in the foregoing embodiment, the voice data synthesis IC is provided in the voice synthesis device 15, this invention is not limited to that, but it may be provided in the auditory emotion expression device 5b. In this case, the voice data synthesis device 15 is arranged such that voice data read from the voice data registration data base 14 is outputted to each channel in the voice data synthesis IC.

Further, in the foregoing embodiment, the voice data registration data base 14 is used as a built-in memory of the pet type robot 1, this invention is not limited to that, it may be used as a memory mounted detachably to the pet type robot 1. A user may remove the voice data registration data base 14 from the pet type robot 1 and mount it back to the pet type robot 1 after writing new voice data on an outside PC, to thereby update the contents of the voice data registration data base 14. In this case, voice data compiled originally on an outside PC may be used, as well as voice data obtained by an outside PC through networks such as the internet, etc. Thus, a user is able to enjoy new pseudo-emotion expressions of the pet type robot 1.

Alternatively, regarding update of the voice data, an interface and a communication device for communicating with outside sources through the interface may be provided in the pet type robot 1, and the interface may be connected to networks such as the internet, etc, or PCs storing voice data, for communication by radio or cables, so that voice data in the voice data registration data base 14 may be updated by downloading the voice data from networks or PCs.

Further, although, in the foregoing embodiment, there are provided a voice data registration data base 14, a voice data synthesis device 15 and an auditory emotion expression device 5b, this invention is not limited to that, the voice registration data base 14, the voice data synthesis device 15 and the auditory emotion expression device 56 may be modularized integrally, and the modularized unit may be mounted detachably to a portion of the auditory emotion expression device 5b in FIG. 4. That is, when the existing pet type robot is required to perform pseudo-emotion expression according to the voice synthesizing method of this invention, in place of the existing auditory emotion expression device 5b, the above described module may be mounted. In such a construction, emotion expression according to the voice synthesizing method of this invention can be performed relatively easily, without need of changing the construction of the existing pet type robot to a large extent.

Further, although in the foregoing embodiment, description has been made regarding execution of the procedure shown by the flow chart in FIG. 6, of a case where a control program stored in a ROM in advance is executed, this invention is not limited to that, a program may be read from a storage medium storing the program showing the procedure, into a RAM to be executed.

Here, the storage medium includes a semiconductor storage medium such as a RAM, a ROM or the like, a magnetic storage medium such as an FD, an HD or the like, an optically readable storage medium such as a CD, a CVD, an LD, a DVD or the like, and a magnetic storage/optically readable storage medium such as an MD or the like, and further any storage medium readable by a computer, whether the reading methology is electrical, magnetic or optical.

Further, although in the foregoing embodiment, the voice synthesis device, the pseudo-emotion expression device and the voice synthesizing method according to this invention are applied, as shown in FIG. 2, to a case where a plurality of different pseudo-emotions generated are expressed through voices, this invention is not limited to that, but may be applied to other cases to the extent that they fall within the spirit of this invention. For example, this invention may be applied to a case where a plurality of different pseudo-emotions are expressed through voices in a virtual pet type robot implemented by software on a computer.

Effect of Invention

In the voice synthesis device according to this invention of embodiment 1 or 2 as described above, a voice corresponding to each pseudo-emotion is synthesized, so that each of a plurality of different pseudo-emotions can be transmitted relatively distinctly to an observer. Thus, attractiveness and cuteness not expected from an actual pet can be expressed.

On the other hand, in the pseudo-emotion expression device according to this invention of embodiments 3-8, a voice corresponding to each pseudo-emotion is synthesized to be outputted, so that each of a plurality of different pseudo-emotions can be transmitted relatively distinctly to an observer. Thus, attractiveness and cuteness not expected from an actual pet can be expressed.

In addition, in the pseudo-emotion expression device according to this invention of embodiment 5, a different synthesized voice can be outputted for each character, so that each of a plurality of different characters can be transmitted relatively distinctly to an observer. Thus, attractiveness and cuteness not expected from an actual pet can be expressed.

Further, in the pseudo-emotion expression device according to this invention of embodiment 6, a different synthesized voice can be outputted for each growing stage, so that each of a plurality of growing stages can be transmitted relatively distinctly to an observer. Thus, attractiveness and cuteness not expected from an actual pet can be expressed.

Furthermore, in the pseudo-emotion expression device according to this invention of embodiment 7, a different synthesized voice can be outputted for each selection by the selection means, so that attractiveness and cuteness not expected from an actual pet can be expressed.

Moreover, in the pseudo-emotion expression device according to this invention of embodiment 8, the intensity of each of a plurality of different pseudo-emotions can be transmitted relatively distinctly to an observer. Thus, attractiveness and cuteness not expected from an actual pet can be expressed.

On the other hand, according to the voice synthesizing method set forth in embodiment 9 of this invention, the same effect as in the voice synthesis device of embodiment 1 can be achieved.

It will be understood by those of skill in the art that numerous and various modifications can be made without departing from the spirit of the present invention. Therefore, it should be clearly understood that the forms of the present invention are illustrative only and are not intended to limit the scope of the present invention.

What is embodimented is:

1. A sound synthesis device used for an interactive device which is capable of interacting with a user, said interactive device comprising a pseudo-emotion generator which is programmed to generate plural pseudo emotions based on signals received by the interaction device, said sound synthesis device comprising:
a sound data memory which stores a different sound assigned to each pseudo emotion;
a sound signal generator which receives signals from the pseudo-emotion generator and accordingly generates a sound signal for each pseudo emotion by retrieving the sound data stored in the sound data memory;
a sound synthesizer which is programmed to synthesize a sound by combining each sound signal from the sound signal generator, wherein the user can recognize overall emotions generated in the interaction device; and
an output device which outputs a synthesized sound to the user.

2. The sound synthesis device according to claim 1, wherein the memory stores multiple sets of sound data, each set defining sounds corresponding to pseudo emotions, and the sound signal generator further comprises a selection device which selects a set of sound data to be used based on a designated selection signal.

3. The sound synthesis device according to claim 2, wherein the designated selection signal is a signal indicating the passage of time.

4. The sound synthesis device according to claim 2, wherein the designated selection signal is a signal indicating the history of interaction between the user and the interactive device.

5. An interactive device capable of interacting with a user, comprising:
a pseudo-emotion generator which is programmed to generate plural pseudo emotions based on signals received by the interaction device; and
a sound synthesis device comprising:
(i) a sound data memory which stores a different sound assigned to each pseudo emotion;
(ii) a sound signal generator which receives signals from the pseudo-emotion generator and accordingly generates a sound signal for each pseudo emotion by retrieving the sound data stored in the sound data memory;
(iii) a sound synthesizer which is programmed to synthesize a sound by combining each sound signal from the sound signal generator, wherein the user can recognize overall emotions generated in the interaction device; and
(iv) an output device which outputs a synthesized sound to the user.

6. The interactive device according to claim 5, wherein the memory stores multiple sets of sound data, each set defining sounds corresponding to pseudo emotions, and the sound signal generator further comprises a selection device which selects a set of sound data to be used based on a designated selection signal.

7. The interactive device according to claim 6, further comprising a growth stage selection unit programmed to select an artificial growth stage based on the passage of time wherein the designated selection signal is a signal indicating the growth stage outputted from the growth stage calculating unit.

8. The interactive device according to claim 6, further comprising a personality selection unit programmed to select a personality based on the history of interaction between the user and the interactive device wherein the designated selection signal is a signal indicating the personality.

9. A method for synthesizing sounds for an interactive device which is capable of interacting with a user, said interactive device comprising a pseudo-emotion generator which is programmed to generate plural pseudo emotions based on signals received by the interaction device, said method comprising:
storing in a sound data memory a different sound assigned to each pseudo emotion;
generating a sound signal for each pseudo emotion generated in the pseudo-emotion generator by retrieving the sound data stored in the sound data memory;
synthesizing a sound by combining each sound signal generated for each pseudo emotion, wherein the user can recognize overall emotions generated in the pseudo-emotion generator; and
outputting a synthesized sound to the user.

10. The method according to claim 9, wherein the memory stores multiple sets of sound data, each set defining sounds corresponding to pseudo emotions, and a set of sound data to be used is selected based on a designated selection signal.

11. The method according to claim 10, wherein the designated selection signal is a signal indicating the passage of time.

12. The method according to claim 10, wherein the designated selection signal is a signal indicating the history of interaction between the user and the interactive device.

13. A sound synthesizing method applied to a pseudo-emotion expression device which utilizes a pseudo-emotion generator for generating a plurality of different pseudo-emotions to express said plurality of pseudo-emotions through sounds, said method characterized in that
when a sound data memory is provided in which sound data is stored for each of said pseudo-emotions, sound data corresponding to each pseudo-emotion generated by said pseudo-emotion generator is read from said sound data memory and synthesized.

14. A sound synthesis device applied to a pseudo-emotion expression device which utilizes a pseudo-emotion generator for generating a plurality of different pseudo-emotions to express said plurality of pseudo-emotions through sounds, said device comprising:
a sound data memory for storing sound data for each of said pseudo-emotions; and a sound data synthesizer for reading from said sound data memory and synthesizing sound data corresponding to each pseudo-emotion generated by said pseudo-emotion generator.

15. A pseudo-emotion expression device for expressing a plurality of pseudo-emotions through sounds, comprising a sound data memory for storing sound data for each of said pseudo-emotions; a pseudo-emotion generator for generating said plurality of pseudo-emotions; a sound data synthesizer for reading from said sound data memory and synthesizing sound data corresponding to each pseudo-emotion generated by said pseudo-emotion generator; and a sound output device for outputting a sound based on sound data synthesized by said sound data synthesizer.

16. The pseudo-emotion expression device according claim 15, further comprising a stimulus recognition device for recognizing stimuli given from the outside, wherein the pseudo-emotion generator generates said plurality of pseudo-emotions based on the recognition result of said stimulus recognition device.

17. The pseudo-emotion expression device according to claim 15 further comprising a character forming device for forming any of a plurality of different characters, wherein said sound data memory is capable of storing, for each of said characters, a sound data correspondence table in which said sound data is registered corresponding to each of said pseudo-emotions; and said sound data synthesizer is adapted to read from said sound memory and synthesize sound data corresponding to each pseudo-emotion generated by said pseudo-emotion generator, by referring to a sound data correspondence table corresponding to a character formed by said character forming device.

18. The pseudo-emotion expression device according to claim 15 further comprising a growing stage specifying device for specifying growing stages, wherein said sound data memory is capable of storing, for each of said growing stages, a sound data correspondence table in which said sound data is registered corresponding to each of said pseudo-emotions; and said sound data synthesizer is adapted to read from said sound memory and synthesize sound data corresponding to each pseudo-emotion generated by said pseudo-emotion generator, by referring to a sound data correspondence table corresponding to a growing stage specified by said growing stage specifying device.

19. The pseudo-emotion expression device according to claim 15, wherein said sound data memory is capable of storing a plurality of sound data correspondence tables in which said sound data is registered corresponding to each of said pseudo-emotions; a table selection device is provided for selecting any of said plurality of sound data correspondence tables; and said sound data synthesizer is adapted to read from said sound memory and synthesize sound data corresponding to each pseudo-emotion generated by said pseudo-emotion generator, by referring to a sound data correspondence table selected by said table selection device.

20. The pseudo-emotion expression device according to claim 15, wherein said pseudo-emotion generator is adapted to generate the intensity of each of said pseudo-emotions; and said sound data synthesizer is adapted to produce an acoustic effect equivalent to the intensity of the pseudo-emotion generated by said pseudo-emotion generator and synthesize said sound data.
